(19) United States
(12) Patent Application Publication
(10) Pub. No.: US 2013/0248848 A1
(43) Pub. Date: Sep. 26, 2013

(54) PROCESS AND MATERIALS FOR MAKING CONTAINED LAYERS AND DEVICES MADE WITH SAME

(71) Applicants: Nora Sabina Radu, Landenberg, PA (US); Adam Fennimore, Wilmington, DE (US)

(72) Inventors: Nora Sabina Radu, Landenberg, PA (US); Adam Fennimore, Wilmington, DE (US)

(73) Assignee: E.I. Du Pont Nemours and Company, Wilmington, DE (US)

(21) Appl. No.: 13/990,812

(22) PCT Filed: Dec. 19, 2011
(86) PCT No.: PCT/US11/65929

§ 371 Date: May 31, 2013

Related U.S. Application Data
(60) Provisional application No. 61/424,848, filed on Dec. 20, 2010.

(51) Int. Cl. H01L 51/00

(52) U.S. Cl. CPC H01L 51/0004
USPC 257/40; 438/99; 438/46

(57) ABSTRACT

There is provided a process for forming a contained second layer over a first layer, including the steps: forming the first layer having a first surface energy; treating the first layer with a priming material to form a priming layer; exposing the priming layer patternwise with radiation resulting in exposed areas and unexposed areas; developing the priming layer to effectively remove the priming layer from the unexposed areas resulting in a first layer having a pattern of priming layer, wherein the pattern of priming layer has a second surface energy that is higher than the first surface energy; and forming the second layer by liquid depositions on the pattern of priming layer on the first layer. The priming material has Formula I

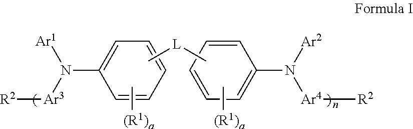

In Formula I: Ar¹ through Ar⁴ are the same or different and are aryl groups; L is a spiro group, an adamantyl group, bicyclic cyclohexyl, deuterated analogs thereof, or substituted derivatives thereof; R¹ is the same or different at each occurrence and is D, F, alkyl, aryl, alkoxy, silyl, or a crosslinkable group, where adjacent R¹ groups can be joined together to form an aromatic ring; R² is the same or different at each occurrence and is H, D, or halogen; a is the same or different at each occurrence and in an integer from 0-4; and n is an integer greater than 0.

### RELATED APPLICATION DATA

This application claims priority under 35 U.S.C. §119(e) from U.S. Provisional Application No. 61/424,848 filed on Dec. 20, 2010, which is incorporated by reference herein in its entirety.

### BACKGROUND INFORMATION

1. Field of the Disclosure

This disclosure relates in general to a process for making an electronic device. It further relates to the device made by the process.

2. Description of the Related Art

Electronic devices utilizing organic active materials are present in many different kinds of electronic equipment. In such devices, an organic active layer is sandwiched between two electrodes.

One type of electronic device is an organic light emitting diode (OLED). OLEDs are promising for display applications due to their high power-conversion efficiency and low processing costs. Such displays are especially promising for battery-powered, portable electronic devices, including cell-phones, personal digital assistants, handheld personal computers, and DVD players. These applications call for displays with high information content, full color, and fast video rate response time in addition to low power consumption.

Current research in the production of full-color OLEDs is directed toward the development of cost effective, high throughput processes for producing color pixels. For the manufacture of monochromatic displays by liquid processing, spin-coating processes have been widely adopted (see, e.g., David Braun and Alan J. Heeger, Appl. Phys. Letters 58, 1982 (1991)). However, manufacture of full-color displays requires certain modifications to procedures used in manufacture of monochromatic displays. For example, to make a display with full-color images, each display pixel is divided into three subpixels, each emitting one of the three primary display colors, red, green, and blue. This division of full-color pixels into three subpixels has resulted in a need to modify current processes to prevent the spreading of the liquid colored materials (i.e., inks) and color mixing.

Several methods for providing ink containment are described in the literature. These are based on containment structures, surface tension discontinuities, and combinations of both. Containment structures are geometric obstacles to spreading: pixel wells, banks, etc. In order to be effective these structures must be large, comparable to the wet thickness of the deposited materials. When the emissive ink is printed into these structures it wets onto the structure surface, so thickness uniformity is reduced near the structure. The terms “emissive” and “light-emitting” are used interchangeably herein. Therefore the structure must be moved outside the emissive “pixel” region so the non-uniformities are not visible in operation. Due to limited space on the display (especially high-resolution displays) this reduces the available emissive area of the pixel. Practical containment structures generally have a negative impact on quality when depositing continuous layers of the charge injection and transport layers. Consequently, all the layers must be printed.

In addition, surface tension discontinuities are obtained when there are either printed or vapor deposited regions of low surface tension materials. These low surface tension materials generally must be applied before printing or coating the first organic active layer in the pixel area. Generally the use of these treatments impacts the quality when coating continuous non-emissive layers, so all the layers must be printed.

An example of a combination of two ink containment techniques is CF₄-plasma treatment of photoresist bank structures (pixel wells, channels). Generally, all of the active layers must be printed in the pixel areas.

All these containment methods have the drawback of precluding continuous coating. Continuous coating of one or more layers is desirable as it can result in higher yields and lower equipment cost. There exists, therefore, a need for improved processes for forming electronic devices.

### SUMMARY

There is provided a process for forming a contained second layer over a first layer, said process comprising:
forming the first layer having a first surface energy;
treating the first layer with a priming material to form a priming layer;
exposing the priming layer patternwise with radiation resulting in exposed areas and unexposed areas;
developing the priming layer to effectively remove the priming layer from either the unexposed areas resulting in a first layer having a pattern of priming layer, wherein the pattern of priming layer has a second surface energy that is higher than the first surface energy; and
forming the second layer on the pattern of priming layer by liquid deposition on the first layer;

wherein the priming material has Formula I

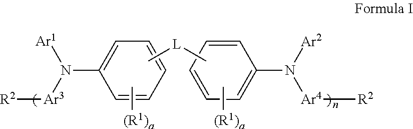

wherein:
Ar¹ through Ar⁴ are the same or different and are aryl groups;
L is selected from the group consisting of a spiro group, an adamantyl group, bicyclic cyclohexyl, deuterated analogs thereof, and substituted derivatives thereof;
R¹ is the same or different at each occurrence and is selected from the group consisting of D, F, alkyl, aryl, alkoxy, silyl, and a crosslinkable group, where adjacent R¹ groups can be joined together to form an aromatic ring;
R² is the same or different at each occurrence and is selected from the group consisting of H, D, and halogen;
a is the same or different at each occurrence and in an integer from 0-4; and
n is an integer greater than 0.

There is also provided a process for making an organic electronic device comprising an electrode having positioned thereover a first organic active layer and a second organic active layer, said process comprising:
forming the first organic active layer having a first surface energy over the electrode;
treating the first organic active layer with a priming material to form a priming layer;
exposing the priming layer patternwise with radiation resulting in exposed areas and unexposed areas;
developing the priming layer to effectively remove the priming layer from the unexposed areas resulting in a first active organic layer having a pattern of priming layer, wherein the pattern of priming layer has a second surface energy that is higher than the first surface energy; and
forming the second organic active layer on the pattern of priming layer by liquid deposition on the first organic active layer;

wherein the priming material has Formula I

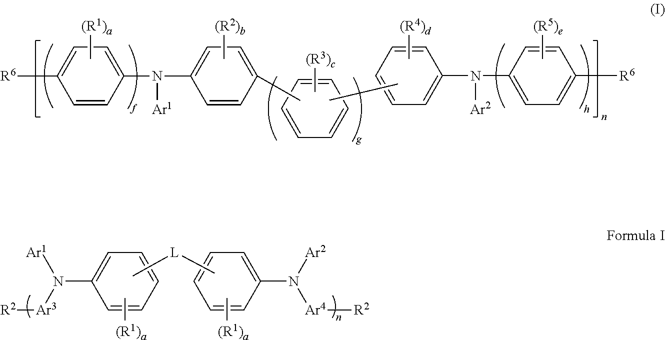

wherein:
Ar¹ through Ar⁴ are the same or different and are aryl groups;
L is selected from the group consisting of a spiro group, an adamantyl group, bicyclic cyclohexyl, deuterated analogs thereof, and substituted derivatives thereof;
R¹ is the same or different at each occurrence and is selected from the group consisting of D, F, alkyl, aryl, alkoxy, silyl, and a crosslinkable group, where adjacent R¹ groups can be joined together to form an aromatic ring;
R² is the same or different at each occurrence and is selected from the group consisting of H, D, and halogen;
a is the same or different at each occurrence and in an integer from 0-4; and
n is an integer greater than 0.

There is also provided an organic electronic device comprising a first organic active layer and a second organic active layer positioned over an electrode, and further comprising a patterned priming layer between the first and second organic active layers, wherein said second organic active layer is present only in areas where the priming layer is present, and wherein the priming layer comprises a material having Formula I

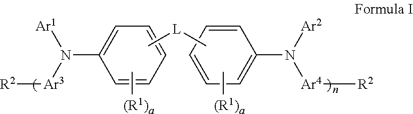

wherein:
Ar¹ through Ar⁴ are the same or different and are aryl groups;
L is selected from the group consisting of a spiro group, an adamantyl group, bicyclic cyclohexyl, deuterated analogs thereof, and substituted derivatives thereof;
R¹ is the same or different at each occurrence and is selected from the group consisting of D, F, alkyl, aryl, alkoxy, silyl, and a crosslinkable group, where adjacent R¹ groups can be joined together to form an aromatic ring;
R² is the same or different at each occurrence and is selected from the group consisting of H, D, and halogen;
a is the same or different at each occurrence and in an integer from 0-4; and
n is an integer greater than 0.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 includes a diagram illustrating contact angle.

FIG. 2 includes an illustration of an organic electronic device.

FIG. 3 includes an illustration of part of an organic electronic device having a priming layer.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

There is provided a process for forming a contained second layer over a first layer, said process comprising:
forming the first layer having a first surface energy;
treating the first layer with a priming material to form a priming layer;
exposing the priming layer patternwise with radiation resulting in exposed areas and unexposed areas;
developing the priming layer to effectively remove the priming layer from either the unexposed areas resulting in a first layer having a pattern of priming layer, wherein the pattern of priming layer has a second surface energy that is higher than the first surface energy; and
forming the second layer on the pattern of priming layer by liquid deposition on the first layer;

wherein the priming material has Formula I

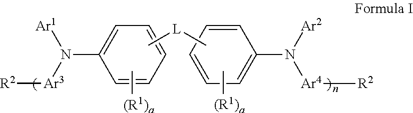

wherein:
Ar¹ through Ar⁴ are the same or different and are aryl groups;
L is selected from the group consisting of a spiro group, an adamantyl group, bicyclic cyclohexyl, deuterated analogs thereof, and substituted derivatives thereof;
R¹ is the same or different at each occurrence and is selected from the group consisting of D, F, alkyl, aryl, alkoxy, silyl, and a crosslinkable group, where adjacent R¹ groups can be joined together to form an aromatic ring;
R² is the same or different at each occurrence and is selected from the group consisting of H, D, and halogen;
a is the same or different at each occurrence and in an integer from 0-4; and
n is an integer greater than 0.

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by the Process, the Priming Material, the Organic Electronic Device, and finally Examples.

### 1. DEFINITIONS AND CLARIFICATION OF TERMS

Before addressing details of embodiments described below, some terms are defined or clarified.

The term “active” when referring to a layer or material, is intended to mean a layer or material that exhibits electronic or electro-radiative properties. In an electronic device, an active material electronically facilitates the operation of the device. Examples of active materials include, but are not limited to, materials which conduct, inject, transport, or block a charge, where the charge can be either an electron or a hole, and materials which emit radiation or exhibit a change in concentration of electron-hole pairs when receiving radiation. Examples of inactive materials include, but are not limited to, planarization materials, insulating materials, and environmental barrier materials.

The term “contained” when referring to a layer, is intended to mean that as the layer is printed, it does not spread significantly beyond the area where it is deposited despite a natural tendency to do so were it not contained. With “chemical containment” the layer is contained by surface energy effects. With “physical containment” the layer is contained by physical barrier structures. A layer may be contained by a combination of chemical containment and physical containment.

The terms “developing” and “development” refer to physical differentiation between areas of a material exposed to radiation and areas not exposed to radiation, and the removal of either the exposed or unexposed areas.

The term “electrode” is intended to mean a member or structure configured to transport carriers within an electronic component. For example, an electrode may be an anode, a cathode, a capacitor electrode, a gate electrode, etc. An electrode may include a part of a transistor, a capacitor, a resistor, an inductor, a diode, an electronic component, a power supply, or any combination thereof.

The term “fluorinated” when referring to an organic compound, is intended to mean that one or more of the hydrogen atoms bound to carbon in the compound have been replaced by fluorine. The term encompasses partially and fully fluorinated materials.

The term “layer” is used interchangeably with the term “film” and refers to a coating covering a desired area. The term is not limited by size. The area can be as large as an entire device or as small as a specific functional area such as the actual visual display, or as small as a single sub-pixel. Layers and films can be formed by any conventional deposition technique, including vapor deposition, liquid deposition (continuous and discontinuous techniques), and thermal transfer. A layer may be highly patterned or may be overall and unpatterned.

The term “liquid composition” is intended to mean a liquid medium in which a material is dissolved to form a solution, a liquid medium in which a material is dispersed to form a dispersion, or a liquid medium in which a material is suspended to form a suspension or an emulsion.

The term “liquid medium” is intended to mean a liquid material, including a pure liquid, a combination of liquids, a solution, a dispersion, a suspension, and an emulsion. Liquid medium is used regardless whether one or more solvents are present.

The term “organic electronic device” is intended to mean a device including one or more organic semiconductor layers or materials. An organic electronic device includes, but is not limited to: (1) a device that converts electrical energy into radiation (e.g., a light-emitting diode, light emitting diode display, diode laser, or lighting panel), (2) a device that detects a signal using an electronic process (e.g., a photodetector, a photoconductive cell, a photoresistor, a photoswitch, a phototransistor, a phototube, an infrared (“IR”) detector, or a biosensors), (3) a device that converts radiation into electrical energy (e.g., a photovoltaic device or solar cell), (4) a device that includes one or more electronic components that include one or more organic semiconductor layers (e.g., a transistor or diode), or any combination of devices in items (1) through (4).

The terms “radiating” and “radiation” refer to adding energy in any form, including heat in any form, the entire electromagnetic spectrum, or subatomic particles, regardless of whether such radiation is in the form of rays, waves, or particles.

The term “surface energy” is the energy required to create a unit area of a surface from a material. A characteristic of surface energy is that liquid materials with a given surface energy will not wet surfaces with a sufficiently lower surface energy. A layer with a low surface energy is more difficult to wet than a layer with a higher surface energy.

As used herein, the term “over” does not necessarily mean that a layer, member, or structure is immediately next to or in contact with another layer, member, or structure. There may be additional, intervening layers, members or structures.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. An alternative embodiment of the disclosed subject matter hereof, is described as consisting essentially of certain features or elements, in which embodiment features or elements that would materially alter the principle of operation or the distinguishing characteristics of the embodiment are not present therein. A further alternative embodiment of the described subject matter hereof is described as consisting of certain features or elements, in which embodiment, or in insubstantial variations thereof, only the features or elements specifically stated or described are present.

Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

### 2. PROCESS

In the process provided herein, a first layer is formed, a priming layer is formed over the first layer, the priming layer is exposed to radiation in a pattern, the priming layer is developed to effectively remove the priming layer from the unexposed areas, resulting in a first layer having a patterned priming layer thereon. By the terms “effectively remove” and “effective removal” it is meant that the priming layer is essentially completely removed in the unexposed areas. The priming layer may also be partially removed in the exposed areas, so that the remaining pattern of priming layer may be thinner than the original priming layer. The pattern of priming layer has a surface energy that is higher than the surface energy of the first layer. A second layer is formed by liquid deposition over and on the pattern of priming layer on the first layer.

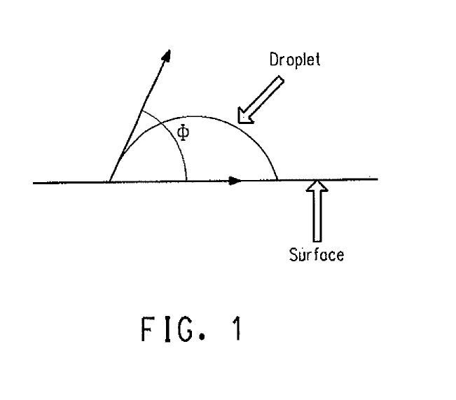

One way to determine the relative surface energies, is to compare the contact angle of a given liquid on the first organic layer to the contact angle of the same liquid on the priming layer after exposure and development (hereinafter referred to as the “developed priming layer”). As used herein, the term “contact angle” is intended to mean the angle φ shown in FIG. 1. For a droplet of liquid medium, angle φ is defined by the intersection of the plane of the surface and a line from the outer edge of the droplet to the surface. Furthermore, angle φ is measured after the droplet has reached an equilibrium position on the surface after being applied, i.e. “static contact angle”. The contact angle increases with decreasing surface energy. A variety of manufacturers make equipment capable of measuring contact angles.

In some embodiments, the first layer has a contact angle with anisole of greater than 40° C.; in some embodiments, greater than 50°; in some embodiments, greater than 60°; in some embodiments, greater than 70°. In some embodiments, the developed priming layer, has a contact angle with anisole of less than 30°; in some embodiments, less than 20°; in some embodiments, less than 10°. In some embodiments, for a given solvent, the contact angle with the developed priming layer is at least 20° lower than the contact angle with the first layer; In some embodiments, for a given solvent, the contact angle with the developed priming layer is at least 30° lower than the contact angle with the first layer; In some embodiments, for a given solvent, the contact angle with the developed priming layer is at least 40° lower than the contact angle with the first layer.

In one embodiment, the first layer is an organic layer deposited on a substrate. The first layer can be patterned or unpatterned. In one embodiment, the first layer is an organic active layer in an electronic device. In one embodiment, the first layer comprises a fluorinated material.

The first layer can be formed by any deposition technique, including vapor deposition techniques, liquid deposition techniques, and thermal transfer techniques. In one embodiment, the first layer is deposited by a liquid deposition technique, followed by drying. In this case, a first material is dissolved or dispersed in a liquid medium. The liquid deposition method may be continuous or discontinuous. Continuous liquid deposition techniques, include but are not limited to, spin coating, roll coating, curtain coating, dip coating, slot-die coating, spray coating, and continuous nozzle coating. Discontinuous liquid deposition techniques include, but are not limited to, ink jet printing, gravure printing, flexographic printing and screen printing. In one embodiment, the first layer is deposited by a continuous liquid deposition technique. The drying step can take place at room temperature or at elevated temperatures, so long as the first material and any underlying materials are not damaged.

The first layer is then treated with a priming layer. By this, it is meant that the priming material is applied over and directly in contact with the first layer to form the priming layer. The priming layer comprises a composition which, when exposed to radiation reacts to form a material that is less removable from the underlying first layer, relative to unexposed priming material. This change must be enough to allow physical differentiation of the exposed and non-exposed areas and development.

In one embodiment, the priming material is polymerizable or crosslinkable.

In one embodiment, the priming material reacts with the underlying area when exposed to radiation. The exact mechanism of this reaction will depend on the materials used. After exposure to radiation, the priming layer is effectively removed in the unexposed areas by a suitable development treatment. In some embodiments, the priming layer is removed only in the unexposed areas. In some embodiments, the priming layer is partially removed in the exposed areas as well, leaving a thinner layer in those areas. In some embodiments, the priming layer that remains in the exposed areas is less than 50 Å in thickness. In some embodiments, the priming layer that remains in the exposed areas is essentially a monolayer in thickness.

In some embodiments, the priming material is deuterated. The term “deuterated” is intended to mean that at least one H has been replaced by D. The term “deuterated analog” refers to a structural analog of a compound or group in which one or more available hydrogens have been replaced with deuterium. In a deuterated compound or deuterated analog, the deuterium is present in at least 100 times the natural abundance level. In some embodiments, the priming material is at least 10% deuterated. By “% deuterated” or “% deuteration” is meant the ratio of deuterons to the sum of protons plus deuterons, expressed as a percentage. In some embodiments, the priming material is at least 20% deuterated; in some embodiments, at least 30% deuterated; in some embodiments, at least 40% deuterated; in some embodiments, at least 50% deuterated; in some embodiments, at least 60% deuterated; in some embodiments, at least 70% deuterated; in some embodiments, at least 80% deuterated; in some embodiments, at least 90% deuterated; in some embodiments, 100% deuterated.

Deuterated priming materials can be less susceptible to degradation by holes, electrons, exitons, or a combination thereof. Deuteration can potentially inhibit degradation of the priming layer during device operation, which in turn can lead to improved device lifetime. In general, this improvement is accomplished without sacrificing other device properties. Furthermore, the deuterated compounds frequently have greater air tolerance than the non-deuterated analogs. This can result in greater processing tolerance both for the preparation and purification of the materials and in the formation of electronic devices using the materials.

The priming layer can be applied by any known deposition process. In one embodiment, the priming layer is applied without adding it to a solvent. In one embodiment, the priming layer is applied by vapor deposition.

In one embodiment, the priming layer is applied by a condensation process. If the priming layer is applied by condensation from the vapor phase, and the surface layer temperature is too high during vapor condensation, the priming layer can migrate into the pores or free volume of an organic substrate surface. In some embodiments, the organic substrate is maintained at a temperature below the glass transition temperature or the melting temperature of the substrate materials. The temperature can be maintained by any known techniques, such as placing the first layer on a surface which is cooled with flowing liquids or gases.

In one embodiment, the priming layer is applied to a temporary support prior to the condensation step, to form a uniform coating of priming layer. This can be accomplished by any deposition method, including liquid deposition, vapor deposition, and thermal transfer. In one embodiment, the priming layer is deposited on the temporary support by a continuous liquid deposition technique. The choice of liquid medium for depositing the priming layer will depend on the exact nature of the priming layer itself. In one embodiment, the material is deposited by spin coating. The coated temporary support is then used as the source for heating to form the vapor for the condensation step.

Application of the priming layer can be accomplished utilizing either continuous or batch processes. For instance, in a batch process, one or more devices would be coated simultaneously with the priming layer and then exposed simultaneously to a source of radiation. In a continuous process, devices transported on a belt or other conveyer device would pass a station when they are sequentially coated with priming layer and then continue past a station where they are sequentially exposed to a source of radiation. Portions of the process may be continuous while other portions of the process may be batch.

In one embodiment, the priming layer is deposited from a second liquid composition. The liquid deposition method can be continuous or discontinuous, as described above. In one embodiment, the priming liquid composition is deposited using a continuous liquid deposition method. The choice of liquid medium for depositing the priming layer will depend on the exact nature of the priming material itself.

After the priming layer is formed, it is exposed to radiation. The type of radiation used will depend upon the sensitivity of the priming layer as discussed above. The exposure is patternwise. As used herein, the term “patternwise” indicates that only selected portions of a material or layer are exposed. Patternwise exposure can be achieved using any known imaging technique. In one embodiment, the pattern is achieved by exposing through a mask. In one embodiment, the pattern is achieved by exposing only select portions with a rastered laser. The time of exposure can range from seconds to minutes, depending upon the specific chemistry of the priming layer used. When lasers are used, much shorter exposure times are used for each individual area, depending upon the power of the laser. The exposure step can be carried out in air or in an inert atmosphere, depending upon the sensitivity of the materials.

In one embodiment, the radiation is selected from the group consisting of ultra-violet radiation (10-390 nm), visible radiation (390-770 nm), infrared radiation (770-10⁶ nm), and combinations thereof, including simultaneous and serial treatments. In one embodiment, the radiation is selected from visible radiation and ultraviolet radiation. In one embodiment, the radiation has a wavelength in the range of 300 to 450 nm. In one embodiment, the radiation is deep UV (200-300 nm). In another embodiment, the ultraviolet radiation has a wavelength between 300 and 400 nm. In another embodiment, the radiation has a wavelength in the range of 400 to 450 nm. In one embodiment, the radiation is thermal radiation. In one embodiment, the exposure to radiation is carried out by heating. The temperature and duration for the heating step is such that at least one physical property of the priming layer is changed, without damaging any underlying layers of the light-emitting areas. In one embodiment, the heating temperature is less than 250° C. In one embodiment, the heating temperature is less than 150° C.

After patternwise exposure to radiation, the priming layer is developed. Development can be accomplished by any known technique. Such techniques have been used extensively in the photoresist and printing art. Examples of development techniques include, but are not limited to, application of heat (evaporation), treatment with a liquid medium (washing), treatment with an absorbant material (blotting), treatment with a tacky material, and the like. The development step results in effective removal of the priming layer in either the unexposed areas. The priming layer then remains in the exposed areas. The priming layer may also be partially removed in the exposed areas, but enough must remain in order for there to be a wettability difference between the exposed and unexposed areas.

In one embodiment, the exposure of the priming layer to radiation results in a change in the solubility or dispersibility of the priming layer in solvents. In this case, development can be accomplished by a wet development treatment. The treatment usually involves washing with a solvent which dissolves, disperses or lifts off one type of area. In one embodiment, the patternwise exposure to radiation results in insolubilization of the exposed areas of the priming layer, and treatment with solvent results in removal of the unexposed areas of the priming layer.

In one embodiment, the exposure of the priming layer to radiation results in a reaction which changes the volatility of the priming layer in exposed areas. In this case, development can be accomplished by a thermal development treatment. The treatment involves heating to a temperature above the volatilization or sublimation temperature of the more volatile material and below the temperature at which the material is thermally reactive. For example, for a polymerizable monomer, the material would be heated at a temperature above the sublimation temperature and below the thermal polymerization temperature. It will be understood that priming materials which have a temperature of thermal reactivity that is close to or below the volatilization temperature, may not be able to be developed in this manner.

In one embodiment, the exposure of the priming layer to radiation results in a change in the temperature at which the material melts, softens or flows. In this case, development can be accomplished by a dry development treatment. A dry development treatment can include contacting an outermost surface of the element with an absorbent surface to absorb or wick away the softer portions. This dry development can be carried out at an elevated temperature, so long as it does not further affect the properties of the remaining areas.

The development step results areas of priming layer that remain and areas in which the underlying first layer is uncovered. In some embodiments, the difference in contact angle with a given solvent for the patterned priming layer and uncovered areas is at least 20°; in some embodiments, at least 30°; in some embodiments, at least 40°.

The second layer is then applied by liquid deposition over and on the developed pattern of priming material on the first layer. In one embodiment, the second layer is a second organic active layer in an electronic device.

The second layer can be applied by any liquid deposition technique. A liquid composition comprising a second material dissolved or dispersed in a liquid medium, is applied over the pattern of developed priming layer, and dried to form the second layer. The liquid composition is chosen to have a surface energy that is greater than the surface energy of the first layer, but approximately the same as or less than the surface energy of the developed priming layer. Thus, the liquid composition will wet the developed priming layer, but will be repelled from the first layer in the areas where the priming layer has been removed. The liquid may spread onto the treated first layer area, but it will de-wet and be contained to the pattern of the developed priming layer. In some embodiments, the second layer is applied by a continuous liquid deposition technique, as described above.

In one embodiment of the process provided herein, the first and second layers are organic active layers. The first organic active layer is formed over a first electrode, a priming layer is formed over the first organic active layer, exposed to radiation and developed to form a pattern of developed priming layer, and the second organic active layer is formed over the developed priming layer on the first organic active layer, such that it is present only over and in the same pattern as the priming layer.

In one embodiment, the first organic active layer is formed by liquid deposition of a first liquid composition comprising the first organic active material and a first liquid medium. The liquid composition is deposited over the first electrode layer, and then dried to form a layer. In one embodiment, the first organic active layer is formed by a continuous liquid deposition method. Such methods may result in higher yields and lower equipment costs.

In one embodiment, the priming is formed by liquid deposition of a second liquid composition comprising the priming material in a second liquid medium. The second liquid medium can be the same as or different from the first liquid medium, so long as it does not damage the first layer. The liquid deposition method can be continuous or discontinuous, as described above. In one embodiment, the priming liquid composition is deposited using a continuous liquid deposition method.

In one embodiment, the second organic active layer is formed by liquid deposition of a third liquid composition comprising the second organic active material and a third liquid medium. The third liquid medium can be the same as or different from the first and second liquid media, so long as it does not damage the first layer or the developed priming layer. In some embodiments, the second organic active layer is formed by printing.

In some embodiments, a third layer is applied over the second layer, such that it is present only over and in the same pattern as the second layer. The third layer can be applied by any of the processes described above for the second layer. In some embodiments, the third layer is applied by a liquid deposition technique. In some embodiments, the third organic active layer is formed by a printing method selected from the group consisting of ink jet printing and continuous nozzle printing.

In some embodiments, the priming material is the same as the second organic active material.

The thickness of the developed priming layer can depend upon the ultimate end use of the material. In some embodiments, the developed priming layer is less than 100 Å in thickness. In some embodiments, the thickness is in the range of 1-50 Å; in some embodiments 5-30 Å.

### 3. PRIMING MATERIAL

The priming material has Formula I

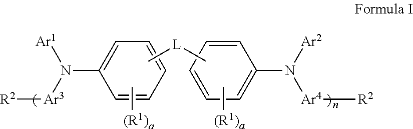

wherein:
Ar¹ through Ar⁴ are the same or different and are aryl groups;
L is selected from the group consisting of a spiro group, an adamantyl group, bicyclic cyclohexyl, deuterated analogs thereof, and substituted derivatives thereof;
R¹ is the same or different at each occurrence and is selected from the group consisting of D, F, alkyl, aryl, alkoxy, silyl, and a crosslinkable group, where adjacent R¹ groups can be joined together to form an aromatic ring;
R² is the same or different at each occurrence and is selected from the group consisting of H, D, and halogen;
a is the same or different at each occurrence and in an integer from 0-4; and
n is an integer greater than 0.

The compound having Formula I can be a small molecule with n=1, an oligomer, or a polymer. In some embodiments, the compound is a polymer with Mₙ>20,000; in some embodiments, Mₙ>50,000.

In some embodiments of Formula I, n=1 and R² is halogen. Such compounds can be useful as monomers for the formation of polymeric compounds. In some embodiments, the halogen is Cl or Br; in some embodiments, Br.

In some embodiments of Formula I, n=1 and R² is H or D.

In some embodiments, the compound having Formula I is deuterated.

The term “deuterated” is intended to mean that at least one H has been replaced by D. The term “deuterated analog” refers to a structural analog of a compound or group in which one or more available hydrogens have been replaced with deuterium. In a deuterated compound or deuterated analog, the deuterium is present in at least 100 times the natural abundance level. In some embodiments, the compound is at least 10% deuterated. By “% deuterated” or “% deuteration” is meant the ratio of deuterons to the sum of protons plus deuterons, expressed as a percentage. In some embodiments, the compound is at least 10% deuterated; in some embodiments, at least 20% deuterated; in some embodiments, at least 30% deuterated; in some embodiments, at least 40% deuterated; in some embodiments, at least 50% deuterated; in some embodiments, at least 60% deuterated; in some embodiments, at least 70% deuterated; in some embodiments, at least 80% deuterated; in some embodiments, at least 90% deuterated; in some embodiments, 100% deuterated.

Deuterated materials can be less susceptible to degradation by holes, electrons, excitons, or a combination thereof. Deuteration can potentially inhibit degradation of the compound during device operation, which in turn can lead to improved device lifetime. In general, this improvement is accomplished without sacrificing other device properties. Furthermore, the deuterated compounds frequently have greater air tolerance than the non-deuterated analogs. This can result in greater processing tolerance both for the preparation and purification of the materials and in the formation of electronic devices using the materials.

In Formula I, the L linking group provides a break in conjugation between two arylamino groups. In some embodiments, the L group provides a degree of linearity such that the angle α, shown below, is greater than the tetrahedral angle of 109.5°.

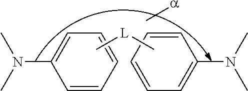

In some embodiments, α is greater than 120°; in some embodiments, greater than 140°; in some embodiments, greater than 160°.

A spiro group is a bicyclic organic compound with rings connected through a single atom. The rings can be different in nature or identical. The connecting atom is called the spiroatom. In some embodiments, the spiroatom is selected from the group consisting of C and Si.

In some embodiments of Formula I, the compounds have L with one of the core structures given below

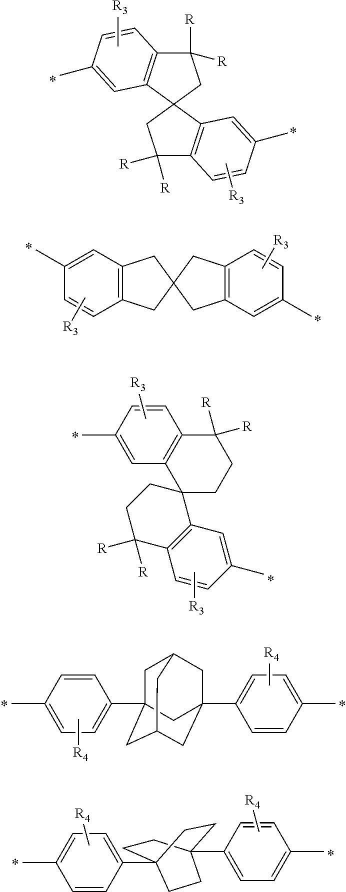

where the asterisk indicates the point of attachment to the nitrogen of the arylamino group and R is the same or different at each occurrence and is H or R¹.

In some embodiments of Formula I, Ar¹ and Ar² are aryl groups having no fused rings. In some embodiments, Ar¹ and Ar² have Formula a Formula a

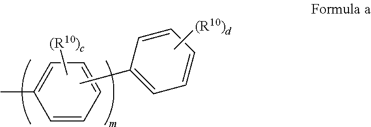

where:
R¹⁰ is the same or different at each occurrence and is selected from the group consisting of D, alkyl, alkoxy, siloxane and silyl;
c is the same or different at each occurrence and is an integer from 0-4:
d is an integer from 0-5; and
m is an integer from 1 to 5.

In some embodiments, Ar¹ and Ar² have Formula b

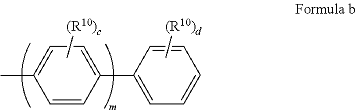

where:
R¹⁰ is the same or different at each occurrence and is selected from the group consisting of D, alkyl, alkoxy, siloxane and silyl;
c is the same or different at each occurrence and is an integer from 0-4:
d is an integer from 0-5; and
m is an integer from 1 to 5.

In some embodiments of Formulae a and b, at least one of c and d is not zero. In some embodiments, m=1-3.

In some embodiments of Formula I, Ar¹ and Ar² are selected from the group consisting of phenyl, biphenyl, terphenyl, deuterated derivatives thereof, and derivatives thereof having one or more substituents selected from the group consisting of alkyl, alkoxy, silyl, and a substituent with a crosslinking group.

In some embodiments of Formula I, a=0.

In some embodiments of Formula I, R¹ is D or C₁₋₁₀ alkyl. In some embodiments, the alkyl group is deuterated. In some embodiments, a=4 and R¹=D.

In some embodiments of Formula I, there can be any combination of the following: (i) deuteration; (ii) the angle α is greater than 109.5°; (iii) L is selected from the group

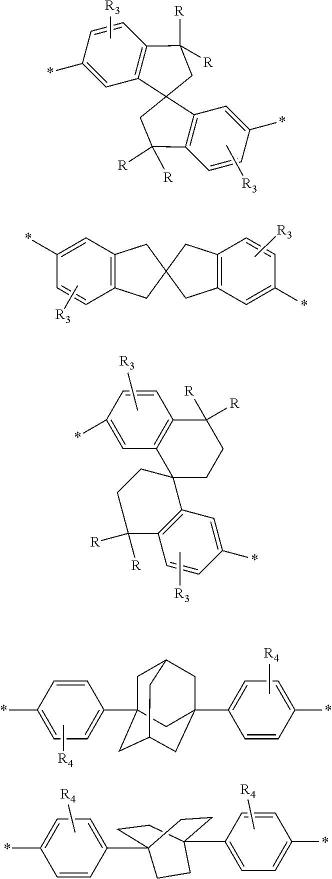

as defined above; (iv) Ar¹ and Ar² are selected from the group consisting of phenyl, biphenyl, terphenyl, deuterated derivatives thereof, derivatives thereof having one or more substituents selected from the group consisting of alkyl, alkoxy, silyl, and a substituent with a crosslinking group, a group having Formula a, and a group having Formula b; (v) a=0 or a is not 0 and R¹ is D, C₁₋₁₀ alkyl, or deuterated C₁₋₁₀ alkyl.

In some embodiments, the compound having Formula I is further defined by Formula II

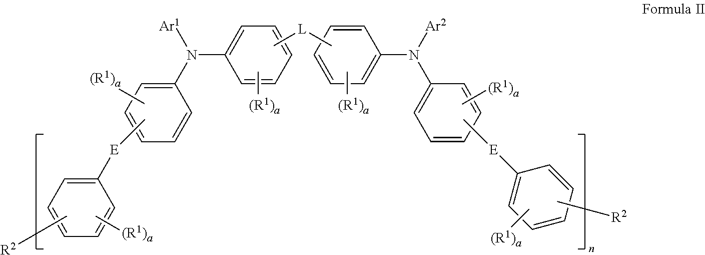

wherein:
Ar¹ and Ar² are the same or different and are aryl groups;
L is selected from the group consisting of a spiro group, an adamantyl group, bicyclic cyclohexyl, deuterated analogs thereof, and substituted derivatives thereof;
E is the same or different at each occurrence and is selected from the group consisting of a single bond, C(R³)₂, C(R⁴)₂C(R⁴)₂, O, Si(R³)₂, Ge(R³)₂;
R¹ is the same or different at each occurrence and is selected from the group consisting of D, F, alkyl, aryl, alkoxy, silyl, and a crosslinkable group, where adjacent R¹ groups can be joined together to form an aromatic ring;
R² is the same or different at each occurrence and is selected from the group consisting of H, D, and halogen;
R³ is the same or different at each occurrence and is selected from the group consisting of alkyl and aryl, where adjacent R³ groups can be joined together to form an aliphatic ring;
R⁴ is the same or different at each occurrence and is selected from the group consisting of H, D, and alkyl;
a is the same or different at each occurrence and is an integer from 0-4; and
n is an integer greater than 0.

The compound having Formula II can be a small molecule with n=1, an oligomer, or a polymer. In some embodiments, the compound is a polymer with Mₙ>20,000; in some embodiments, Mₙ>50,000.

In some embodiments of Formula II, n=1 and R² is halogen. Such compounds can be useful as monomers for the formation of polymeric compounds. In some embodiments, the halogen is Cl or Br; in some embodiments, Br.

In some embodiments of Formula II, n=1 and R² is H or D.

In some embodiments, the compound having Formula II is deuterated.

In some embodiments of Formula II, L is selected from the groups shown below

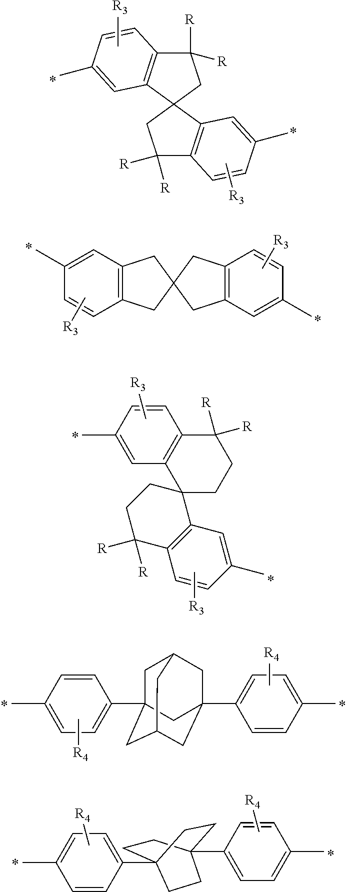

where the asterisk indicates the point of attachment to the nitrogen of the arylamino group and R is the same or different at each occurrence and is H or R¹.

In some embodiments of Formula II, Ar¹ and Ar² are aryl groups having no fused rings. In some embodiments, Ar¹ and Ar² have Formula a or Formula b, as defined above. In some embodiments of Formulae a and b, at least one of c and d is not zero. In some embodiments, m=1-3.

In some embodiments of Formula II. Ar¹ and Ar² are selected from the group consisting of phenyl, biphenyl, terphenyl, deuterated derivatives thereof, and derivatives thereof having one or more substituents selected from the group consisting of alkyl, alkoxy, silyl, and a substituent with a crosslinking group.

In some embodiments of Formula I, a=0.

In some embodiments of Formula I, R¹ is D or C₁₋₁₀ alkyl. In some embodiments, the alkyl group is deuterated. In some embodiments, a=4 and R¹=D.

In some embodiments of Formula II, E is selected from the group consisting of C(R³)₂ and C(R⁴)₂C(R⁴)₂. In some embodiments, R³ is selected from the group consisting of phenyl, biphenyl, and fluoroalkyl. In some embodiments, R⁴ is selected from the group consisting of H and D.

In some embodiments of Formula II, there can be any combination of the following: (i) deuteration; (ii) the angle α is greater than 109.50; (iii) L is selected from the group

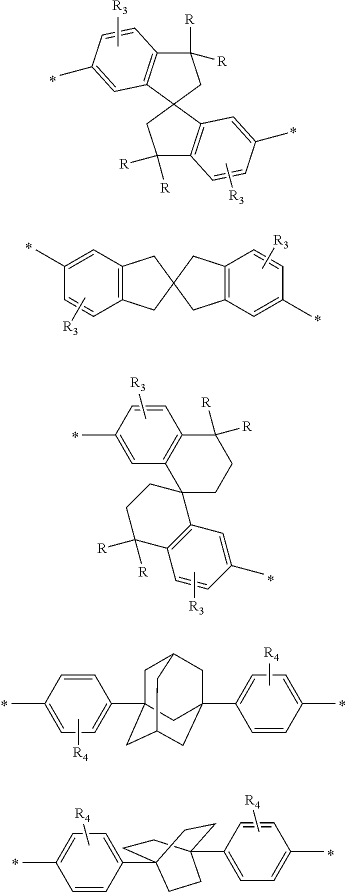

as defined above; (iv) Ar¹ and Ar² are selected from the group consisting of phenyl, biphenyl, terphenyl, deuterated derivatives thereof, derivatives thereof having one or more substituents selected from the group consisting of alkyl, alkoxy, silyl, and a substituent with a crosslinking group, a group having Formula a, and a group having Formula b; (v) a=0, or a is not 0 and R¹ is D, C₁₋₁₀ alkyl, or deuterated C₁₋₁₀ alkyl; (vi) E is selected from the group consisting of C(R³)₂ and C(R⁴)₂C(R⁴)₂; (vii) R³ is selected from the group consisting of phenyl, biphenyl, and fluoroalkyl; (viii) R⁴ is selected from the group consisting of H and D. In some embodiments, the compound having Formula I is further defined by Formula III

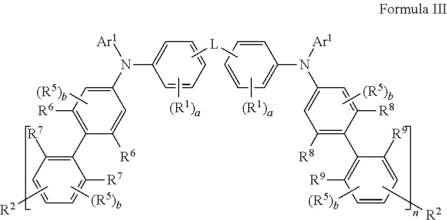

wherein:
Ar¹ and Ar² are the same or different and are aryl groups;
L is selected from the group consisting of a spiro group, an adamantyl group, bicyclic cyclohexyl, deuterated analogs thereof, and substituted derivatives thereof;
R¹ is the same or different at each occurrence and is selected from the group consisting of D, F, alkyl, aryl, alkoxy, silyl, and a crosslinkable group, where adjacent R¹ groups can be joined together to form an aromatic ring;
R² is the same or different at each occurrence and is selected from the group consisting of H, D, and halogen;
R⁵ is the same or different at each occurrence and is selected from the group consisting of D, F, alkyl, aryl, alkoxy, silyl, and a crosslinkable group;
R⁶ through R⁹ are the same or different at each occurrence and are selected from the group consisting of H, D, F, alkyl, aryl, alkoxy, silyl, and a crosslinkable group, with the proviso that at least one of R⁶ and R⁷ is alkyl or silyl, and at least one of R⁸ and R⁹ is alkyl or silyl;
a is the same or different at each occurrence and is an integer from 0-4;
b is the same or different at each occurrence and is an integer from 0-2; and
n is an integer greater than 0.

The compound having Formula III can be a small molecule with n=1, an oligomer, or a polymer. In some embodiments, the compound is a polymer with Mₙ>20,000; in some embodiments, Mₙ>50,000.

In some embodiments of Formula III, n=1 and R² is halogen. Such compounds can be useful as monomers for the formation of polymeric compounds. In some embodiments, the halogen is Cl or Br; in some embodiments, Br.

In some embodiments of Formula III, n=1 and R² is H or D.

In some embodiments, the compound having Formula III is deuterated.

In some embodiments of Formula III, L is selected from the groups shown below

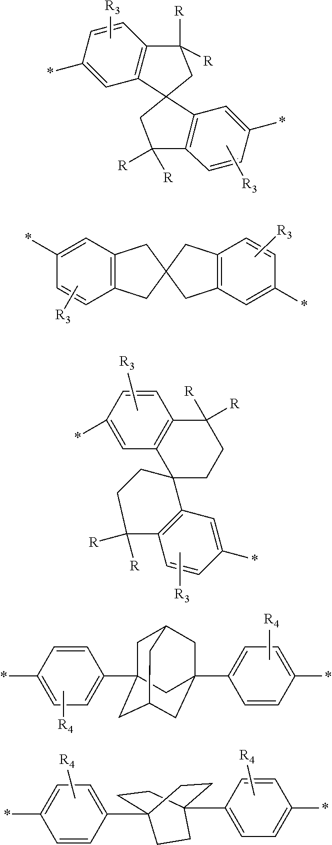

where the asterisk indicates the point of attachment to the nitrogen of the arylamino group and R is the same or different at each occurrence and is H or R¹.

In some embodiments of Formula III, Ar¹ and Ar² are aryl groups having no fused rings. In some embodiments, Ar¹ and Ar² have Formula a or Formula b, as defined above. In some embodiments of Formulae a and b, at least one of c and d is not zero. In some embodiments, m=1-3.

In some embodiments of Formula III, Ar¹ and Ar² are selected from the group consisting of phenyl, biphenyl, terphenyl, deuterated derivatives thereof, and derivatives thereof having one or more substituents selected from the group consisting of alkyl, alkoxy, silyl, and a substituent with a crosslinking group.

In some embodiments of Formula III, all a=0.

In some embodiments of Formula III, a is not 0 and R¹ is D or C₁₋₁₀ alkyl. In some embodiments, the alkyl group is deuterated. In some embodiments, all a=4 and R¹=D.

In some embodiments of Formula III, all b=0.

In some embodiments of Formula III, b is not 0 and R² is D or C₁₋₁₀ alkyl. In some embodiments, the alkyl group is deuterated. In some embodiments, all b=2 and R²=D.

In some embodiments of Formula III, R⁶═R⁸=alkyl or deuterated alkyl. In some embodiments, R¹═R⁹=alkyl or deuterated alkyl.

In some embodiments of Formula III, there can be any combination of the following: (i) deuteration; (ii) the angle α is greater than 109.50; (iii) L is selected from the group

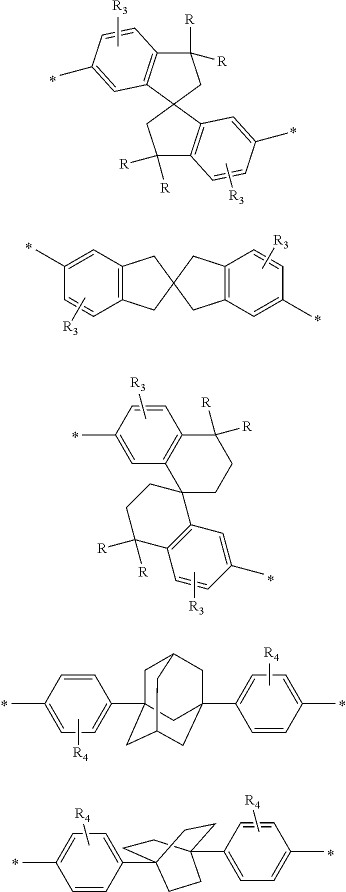

as defined above; (iv) Ar¹ and Ar² are selected from the group consisting of phenyl, biphenyl, terphenyl, deuterated derivatives thereof, derivatives thereof having one or more substituents selected from the group consisting of alkyl, alkoxy, silyl, and a substituent with a crosslinking group, a group having Formula a, and a group having Formula b; (v) a=0, or a is not 0 and R¹ is D, C₁₋₁₀ alkyl, or deuterated C₁₋₁₀ alkyl; (vi) b=0, or b is not 0 and R² is D, C₁₋₁₀ alkyl, or deuterated C₁₋₁₀ alkyl; (vii) R⁶═R⁸=alkyl or deuterated alkyl; (viii) R¹═R⁹=alkyl or deuterated alkyl.

Some non-limiting examples of compounds having Formula I are shown below.

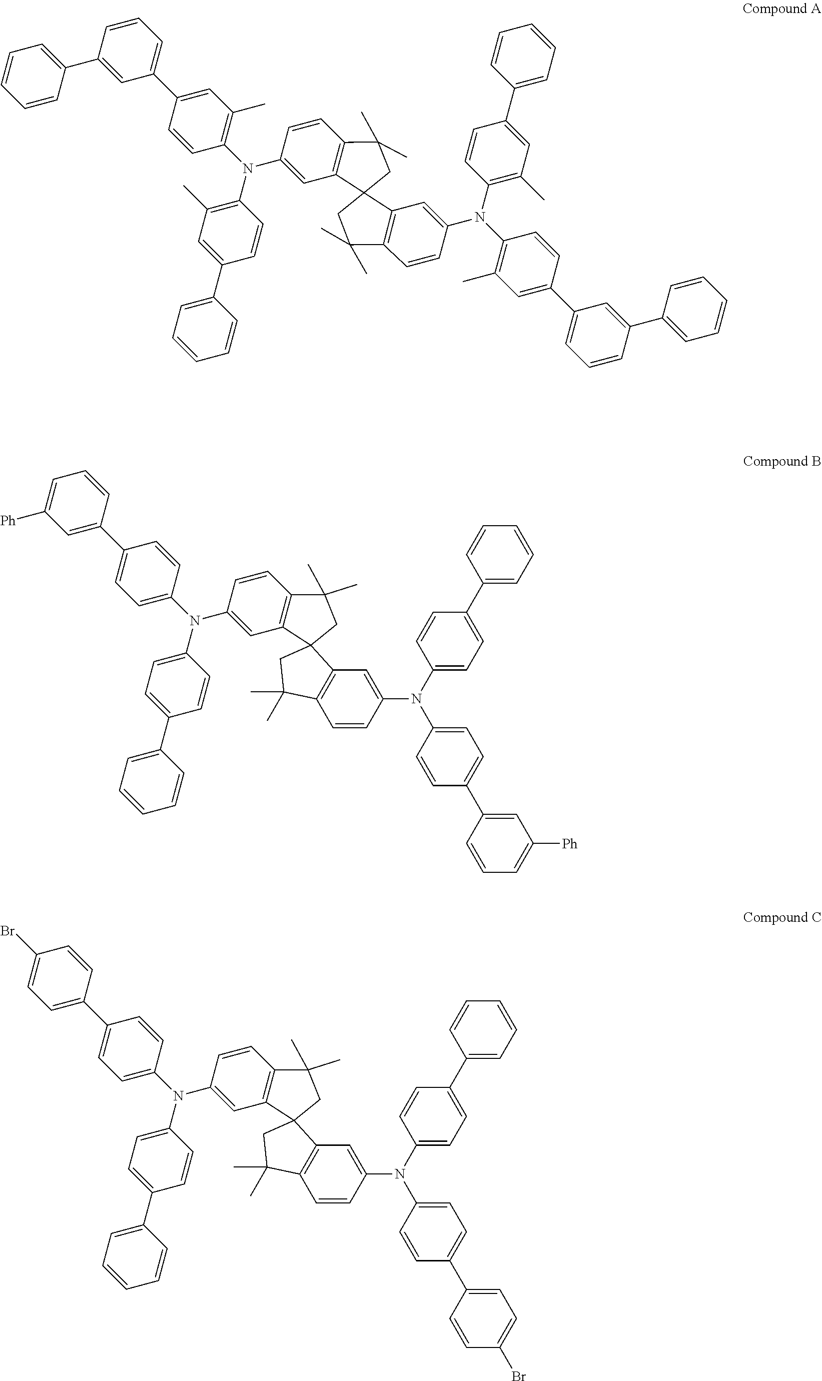 [SMILES: Cc1cc(-c2ccccc2)ccc1N(c1ccc2c(c1)C1(CC2(C)C)CC(C)(C)c2ccc(N(c3ccc(-c4ccccc4)cc3C)c3ccc(-c4cccc(-c5ccccc5)c4)cc3C)cc21)c1ccc(-c2cccc(-c3ccccc3)c2)cc1C ; CC1(C)CC2(CC(C)(C)c3ccc(N(c4ccc(-c5ccccc5)cc4)c4ccc(-c5cccc(-c6ccccc6)c5)cc4)cc32)c2cc(N(c3ccc(-c4ccccc4)cc3)c3ccc(-c4cccc(-c5ccccc5)c4)cc3)ccc21 ; CC1(C)CC2(CC(C)(C)c3ccc(N(c4ccc(-c5ccccc5)cc4)c4ccc(-c5ccc(Br)cc5)cc4)cc32)c2cc(N(c3ccc(-c4ccccc4)cc3)c3ccc(-c4ccc(Br)cc4)cc3)ccc21]

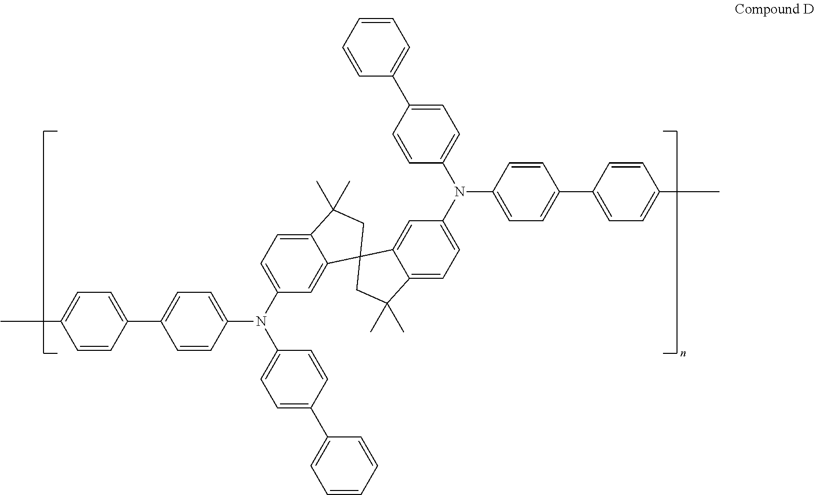

The new compounds can be made using any technique that will yield a C—C or C—N bond. A variety of such techniques are known, such as Suzuki, Yamamoto, Stille, and Pd- or Ni-catalyzed C—N couplings. Deuterated compounds can be prepared in a similar manner using deuterated precursor materials or, more generally, by treating the non-deuterated compound with deuterated solvent, such as d6-benzene, in the presence of a Lewis acid H/D exchange catalyst, such as aluminum trichloride or ethyl aluminum dichloride. Exemplary preparations are given in the Examples.

The compounds can be formed into layers using solution processing techniques. The term “layer” is used interchangeably with the term “film” and refers to a coating covering a desired area. The term is not limited by size. The area can be as large as an entire device or as small as a specific functional area such as the actual visual display, or as small as a single sub-pixel. Layers and films can be formed by any conventional deposition technique, including vapor deposition, liquid deposition (continuous and discontinuous techniques), and thermal transfer. Continuous deposition techniques, include but are not limited to, spin coating, gravure coating, curtain coating, dip coating, slot-die coating, spray coating, and continuous nozzle coating. Discontinuous deposition techniques include, but are not limited to, ink jet printing, gravure printing, and screen printing.

### 4. ORGANIC ELECTRONIC DEVICE

The process will be further described in terms of its application in an electronic device, although it is not limited to such application.

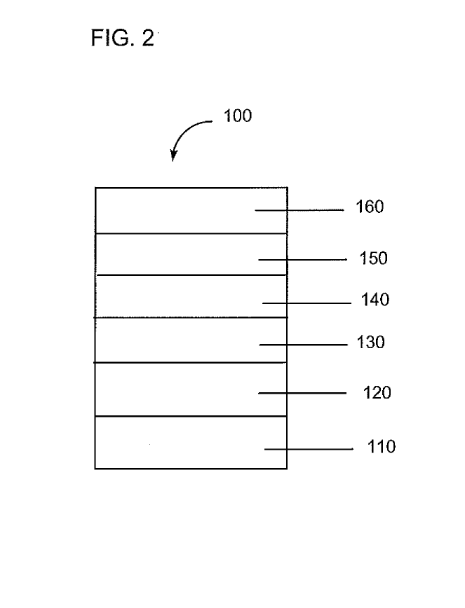

FIG. 2 is an exemplary electronic device, an organic light-emitting diode (OLED) display that includes at least two organic active layers positioned between two electrical contact layers. The electronic device 100 includes one or more layers 120 and 130 to facilitate the injection of holes from the anode layer 110 into the emissive layer 140. In general, when two layers are present, the layer 120 adjacent the anode is called the hole injection layer, sometimes called a buffer layer. The layer 130 adjacent to the emissive layer is called the hole transport layer. An optional electron transport layer 150 is located between the emissive layer 140 and a cathode layer 160. The organic layers 120 through 150 are individually and collectively referred to an the organic active layers of the device. Depending on the application of the device 100, the emissive layer 140 can be a light-emitting layer that is activated by an applied voltage (such as in a light-emitting diode or light-emitting electrochemical cell), a layer of material that responds to radiant energy and generates a signal with or without an applied bias voltage (such as in a photodetector). The device is not limited with respect to system, driving method, and utility mode. The priming layer is not shown in this diagram.

For multicolor devices, the emissive layer 140 is made up different areas of at least three different colors. The areas of different color can be formed by printing the separate colored areas. Alternatively, it can be accomplished by forming an overall layer and doping different areas of the layer with emissive materials with different colors. Such a process has been described in, for example, published U.S. patent application 2004-0094768.

In some embodiments, the new process described herein can be used for any successive pairs of organic layers in the device, where the second layer is to be contained in a specific area. The process for making an organic electronic device comprising an electrode having positioned thereover a first organic active layer and a second organic active layer, comprises:

forming the first organic active layer having a first surface energy over the electrode;

treating the first organic active layer with a priming material to form a priming layer;

exposing the priming layer patternwise with radiation resulting in exposed areas and unexposed areas;

developing the priming layer to remove the priming layer from the unexposed areas resulting in a first active organic layer having a pattern of priming layer, wherein the pattern of priming layer has a second surface energy that is higher than the first surface energy; and

forming the second organic active layer by liquid deposition on the pattern of priming layer on the first organic active layer;

wherein the priming material has Formula I, as described above.

In one embodiment of the new process, the second organic active layer is the emissive layer 140, and the first organic active layer is the device layer applied just before layer 140. In many cases the device is constructed beginning with the anode layer. When the hole transport layer 130 is present, the priming layer would be applied to layer 130 and developed prior to applying the emissive layer 140. When layer 130 was not present, the priming layer would be applied to layer 120. In the case where the device was constructed beginning with the cathode, the priming layer would be applied to the electron transport layer 150 prior to applying the emissive layer 140.

In one embodiment of the new process, the first organic active layer is the hole injection layer 120 and the second organic active layer is the hole transport layer 130. In the embodiment where the device is constructed beginning with the anode layer, the priming layer is applied to hole injection layer 120 and developed prior to applying the hole transport layer 130. In one embodiment, the hole injection layer comprises a fluorinated material, in one embodiment, the hole injection layer comprises a conductive polymer doped with a fluorinated acid polymer. In one embodiment, the hole injection layer consists essentially of a conductive polymer doped with a fluorinated acid polymer. In some embodiments, the priming layer consists essentially of hole transport material. In one embodiment, the priming layer consists essentially of the same hole transport material as the hole transport layer.

The layers in the device can be made of any materials which are known to be useful in such layers. The device may include a support or substrate (not shown) that can be adjacent to the anode layer 110 or the cathode layer 160. Most frequently, the support is adjacent the anode layer 110. The support can be flexible or rigid, organic or inorganic. Generally, glass or flexible organic films are used as a support. The anode layer 110 is an electrode that is more efficient for injecting holes compared to the cathode layer 160. The anode can include materials containing a metal, mixed metal, alloy, metal oxide or mixed oxide. Suitable materials include the mixed oxides of the Group 2 elements (i.e., Be, Mg, Ca, Sr, Ba), the Group 11 elements, the elements in Groups 4, 5, and 6, and the Group 8-10 transition elements. If the anode layer 110 is to be light transmitting, mixed oxides of Groups 12, 13 and 14 elements, such as indium-tin-oxide, may be used. As used herein, the phrase “mixed oxide” refers to oxides having two or more different cations selected from the Group 2 elements or the Groups 12, 13, or 14 elements. Some non-limiting, specific examples of materials for anode layer 110 include, but are not limited to, indium-tin-oxide (“ITO”), aluminum-tin-oxide, aluminum-zinc-oxide, gold, silver, copper, and nickel. The anode may also comprise an organic material such as polyaniline, polythiophene, or polypyrrole.

The anode layer 110 may be formed by a chemical or physical vapor deposition process or spin-cast process. Chemical vapor deposition may be performed as a plasma-enhanced chemical vapor deposition (“PECVD”) or metal organic chemical vapor deposition (“MOCVD”). Physical vapor deposition can include all forms of sputtering, including ion beam sputtering, as well as e-beam evaporation and resistance evaporation. Specific forms of physical vapor deposition include rf magnetron sputtering and inductively-coupled plasma physical vapor deposition (“IMP-PVD”). These deposition techniques are well known within the semiconductor fabrication arts.

Usually, the anode layer 110 is patterned during a lithographic operation. The pattern may vary as desired. The layers can be formed in a pattern by, for example, positioning a patterned mask or resist on the first flexible composite barrier structure prior to applying the first electrical contact layer material. Alternatively, the layers can be applied as an overall layer (also called blanket deposit) and subsequently patterned using, for example, a patterned resist layer and wet chemical or dry etching techniques. Other processes for patterning that are well known in the art can also be used. When the electronic devices are located within an array, the anode layer 110 typically is formed into substantially parallel strips having lengths that extend in substantially the same direction.

The hole injection layer 120 functions to facilitate injection of holes into the emissive layer and to planarize the anode surface to prevent shorts in the device. Hole injection materials may be polymers, oligomers, or small molecules, and may be in the form of solutions, dispersions, suspensions, emulsions, colloidal mixtures, or other compositions.

The hole injection layer can be formed with polymeric materials, such as polyaniline (PANI) or polyethylenedioxythiophene (PEDOT), which are often doped with protonic acids. The protonic acids can be, for example, poly(styrenesulfonic acid), poly(2-acrylamido-2-methyl-1-propanesulfonic acid), and the like. The hole injection layer 120 can comprise charge transfer compounds, and the like, such as copper phthalocyanine and the tetrathiafulvalene-tetracyanoquinodimethane system (TTF-TCNQ). In one embodiment, the hole injection layer 120 is made from a dispersion of a conducting polymer and a colloid-forming polymeric acid. Such materials have been described in, for example, published U.S. patent applications US 2004/0102577, US 2004/0127637, US 2005/0205860, and published PCT application WO 2009/018009.

The hole injection layer 120 can be applied by any deposition technique. In one embodiment, the hole injection layer is applied by a solution deposition method, as described above. In one embodiment, the hole injection layer is applied by a continuous solution deposition method.

Layer 130 comprises hole transport material. Examples of hole transport materials for the hole transport layer have been summarized for example, in Kirk-Othmer Encyclopedia of Chemical Technology, Fourth Edition, Vol. 18, p. 837-860, 1996, by Y. Wang. Both hole transporting small molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1,1′-biphenyl]-4,4′-diamine (TPD); 4,4′-bis(carbazol-9-yl)biphenyl (CBP); 1,3-bis(carbazol-9-yl)benzene (mCP); 1,1-bis[(di-4-tolylamino) phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′,N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate.

In some embodiments, the hole transport layer comprises a hole transport polymer. In some embodiments, the hole transport layer consists essentially of a hole transport polymer. In some embodiments, the hole transport polymer is a distyrylaryl compound. In some embodiments, the aryl group is has two or more fused aromatic rings. In some embodiments, the aryl group is an acene. The term “acene” as used herein refers to a hydrocarbon parent component that contains two or more ortho-fused benzene rings in a straight linear arrangement.

In some embodiments, the hole transport polymer is an arylamine polymer. In some embodiments, it is a copolymer of fluorene and arylamine monomers.

In some embodiments, the polymer has crosslinkable groups. In some embodiments, crosslinking can be accomplished by a heat treatment and/or exposure to UV or visible radiation. Examples of crosslinkable groups include, but are not limited to vinyl, acrylate, perfluorovinylether, 1-benzo-3,4-cyclobutane, siloxane, and methyl esters. Crosslinkable polymers can have advantages in the fabrication of solution-process OLEDs. The application of a soluble polymeric material to form a layer which can be converted into an insoluble film subsequent to deposition, can allow for the fabrication of multilayer solution-processed OLED devices free of layer dissolution problems.

Examples of crosslinkable polymers can be found in, for example, published US patent application 2005/0184287 and published PCT application WO 2005/052027.

In some embodiments, the hole transport layer comprises a polymer which is a copolymer of 9,9-dialkylfluorene and triphenylamine. In some embodiments, the hole transport layer consists essentially of a polymer which is a copolymer of 9,9-dialkylfluorene and triphenylamine. In some embodiments, the polymer is a copolymer of 9,9-dialkylfluorene and 4,4′-bis(diphenylamino)biphenyl. In some embodiments, the polymer is a copolymer of 9,9-dialkylfluorene and TPB. In some embodiments, the polymer is a copolymer of 9,9-dialkylfluorene and NPB. In some embodiments, the copolymer is made from a third comonomer selected from (vinylphenyl)diphenylamine and 9,9-distyrylfluorene or 9,9-di(vinylbenzyl)fluorene. In some embodiments, the hole transport layer comprises a material comprising triarylamines having conjugated moieties which are connected in a non-planar configuration. Such materials can be monomeric or polymeric. Examples of such materials have been described in, for example, published PCT application WO 2009/067419.

In some embodiments, the hole transport layer is doped with a p-dopant, such as tetrafluorotetracyanoquinodimethane and perylene-3,4,9,10-tetracarboxylic-3,4,9,10-dianhydride.

In some embodiments, the hole transport layer comprises a material having Formula I, as described above. In some embodiments, the hole transport layer consists essentially of a material having Formula I.

The hole transport layer 130 can be applied by any deposition technique. In one embodiment, the hole transport layer is applied by a solution deposition method, as described above. In one embodiment, the hole transport layer is applied by a continuous solution deposition method.

Depending upon the application of the device, the emissive layer 140 can be a light-emitting layer that is activated by an applied voltage (such as in a light-emitting diode or light-emitting electrochemical cell), a layer of material that responds to radiant energy and generates a signal with or without an applied bias voltage (such as in a photodetector). In one embodiment, the emissive material is an organic electroluminescent (“EL”) material. Any EL material can be used in the devices, including, but not limited to, small molecule organic fluorescent compounds, fluorescent and phosphorescent metal complexes, conjugated polymers, and mixtures thereof. Examples of fluorescent compounds include, but are not limited to, chrysenes, pyrenes, perylenes, rubrenes, coumarins, anthracenes, thiadiazoles, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 031040257, and mixtures thereof. In some cases the small molecule fluorescent or organometallic materials are deposited as a dopant with a host material to improve processing and/or electronic properties. Examples of conjugated polymers include, but are not limited to poly(phenylenevinylenes), polyfluorenes, poly(spirobifluorenes), polythiophenes, poly(p-phenylenes), copolymers thereof, and mixtures thereof.

The emissive layer 140 can be applied by any deposition technique. In one embodiment, the emissive layer is applied by a solution deposition method, as described above. In one embodiment, the emissive layer is applied by a continuous solution deposition method.

Optional layer 150 can function both to facilitate electron transport, and also serve as a buffer layer or confinement layer to prevent quenching of the exciton at layer interfaces. Preferably, this layer promotes electron mobility and reduces exciton quenching. Examples of electron transport materials which can be used in the optional electron transport layer 150, include metal chelated oxinoid compounds, including metal quinolate derivatives such as tris(8-hydroxyquinolato)aluminum (AlQ), bis(2-methyl-8-quinolinolato)(p-phenylphenolato) aluminum (BAlq), tetrakis-(8-hydroxyquinolato)hafnium (HfQ) and tetrakis-(8-hydroxyquinolato)zirconium (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); and mixtures thereof. In some embodiments, the electron transport layer further comprises an n-dopant. N-dopant materials are well known. The n-dopants include, but are not limited to, Group 1 and 2 metals; Group 1 and 2 metal salts, such as LiF, CsF, and Cs₂CO₃; Group 1 and 2 metal organic compounds, such as Li quinolate; and molecular n-dopants, such as leuco dyes, metal complexes, such as W₂(hpp)₄ where hpp=1,3,4,6,7,8-hexahydro-2H-pyrimido-[1,2-a]-pyrimidine and cobaltocene, tetrathianaphthacene, bis(ethylenedithio)tetrathiafulvalene, heterocyclic radicals or diradicals, and the dimers, oligomers, polymers, dispiro compounds and polycycles of heterocyclic radical or diradicals.

The electron transport layer 150 is usually formed by a chemical or physical vapor deposition process.

The cathode 160, is an electrode that is particularly efficient for injecting electrons or negative charge carriers. The cathode can be any metal or nonmetal having a lower work function than the anode. Materials for the cathode can be selected from alkali metals of Group 1 (e.g., Li, Cs), the Group 2 (alkaline earth) metals, the Group 12 metals, including the rare earth elements and lanthanides, and the actinides. Materials such as aluminum, indium, calcium, barium, samarium and magnesium, as well as combinations, can be used. Li-containing organometallic compounds, LiF, Li₂O, Cs-containing organometallic compounds, CsF, Cs₂O, and Cs₂CO₃ can also be deposited prior to deposition of the cathode layer to lower the operating voltage. This layer may be referred to as an electron injection layer.

The cathode layer 160 is usually formed by a chemical or physical vapor deposition process.

In some embodiments, additional layers(s) may be present within organic electronic devices.

It is understood that each functional layer can be made up of more than one layer.

In one embodiment, the different layers have the following range of thicknesses: anode 110, 100-5000 Å, in one embodiment 100-2000 Å; hole injection layer 120, 50-2500 Å, in one embodiment 200-1000 Å; hole transport layer 130, 50-2500 Å, in one embodiment 200-1000 Å; emissive layer 140, 10-2000 Å, in one embodiment 100-1000 Å; electron transport layer 150, 50-2000 Å, in one embodiment 100-1000 Å; cathode 160, 200-10000 Å, in one embodiment 300-5000 Å. When an electron injection layer is present, the amount of material deposited is generally in the range of 1-100 Å, in one embodiment 1-10 Å. The desired ratio of layer thicknesses will depend on the exact nature of the materials used.

in some embodiments, there is provided an organic electronic device comprising a first organic active layer and a second organic active layer positioned over an electrode, and further comprising a patterned priming layer between the first and second organic active layers, wherein said second organic active layer is present only in areas where the priming layer is present, and wherein the priming layer comprises a material having Formula I, as described above. In some embodiments, the priming layer consists essentially of a material having Formula I. In some embodiments, the first organic active layer comprises a conductive polymer and a fluorinated acid polymer. In some embodiments, the second organic active layer comprises hole transport material. In some embodiments, the first organic active layer comprises a conductive polymer doped with a fluorinated acid polymer and the second organic active layer consists essentially of hole transport material.

In some embodiments, there is provided a process for making an organic electronic device comprising an anode having thereon a hole injection layer and a hole transport layer, said process comprising:

forming the hole injection layer over the anode, said hole injection layer comprising a fluorinated material and having a first surface energy;

forming a priming layer directly on the hole injection layer;

exposing the priming layer patternwise with radiation resulting in exposed areas and unexposed areas;

developing the priming layer to effectively remove the priming layer from the unexposed areas resulting in a pattern of developed priming layer on the hole injection layer, said developed priming layer having a second surface energy that is higher than the first surface energy; and

forming a hole transport layer by liquid deposition on the developed pattern of priming layer;

wherein the priming layer comprises a material having Formula I, as described above.

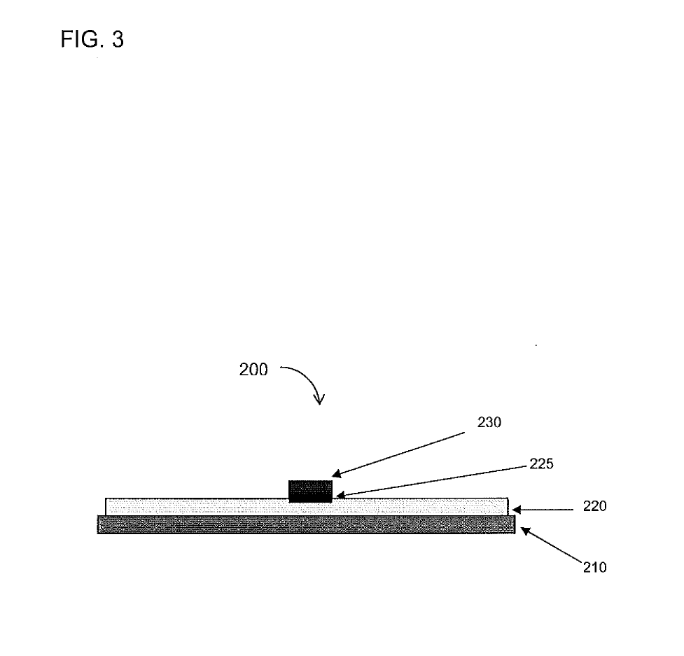

This is shown schematically in FIG. 3. Device 200 has an anode 210 on a substrate (not shown). On the anode is hole injection layer 220. The developed priming layer is shown as 225. The surface energy of the hole injection layer 220 is less than the surface energy of the priming layer 225. When the hole transport layer 230 is deposited over the priming layer and hole injection layer, it does not wet the low energy surface of the hole injection layer and remains only over the pattern of the priming layer.

In some embodiments, the hole injection layer comprises a conductive polymer doped with a fluorinated acid polymer. In some embodiments, the hole injection layer consists essentially of a conductive polymer doped with a fluorinated acid polymer. In some embodiments, the hole injection layer consists essentially of a conductive polymer doped with a fluorinated acid polymer and inorganic nanoparticles. In some embodiments, the inorganic nanoparticles are selected from the group consisting of silicon oxide, titanium oxides, zirconium oxide, molybdenum trioxide, vanadium oxide, aluminum oxide, zinc oxide, samarium oxide, yttrium oxide, cesium oxide, cupric oxide, stannic oxide, antimony oxide, and combinations thereof. Such materials have been described in, for example, published U.S. patent applications US 2004/0102577, US 2004/0127637, US 2005/0205860, and published PCT application WO 2009/018009.

In some embodiments, the priming layer consists essentially of a material having Formula I.

In some embodiments, the hole transport layer is selected from the group consisting of triarylamines, carbazoles, polymeric analogs thereof, and combinations thereof. In some embodiments, the hole transport layer is selected from the group consisting of polymeric triarylamines, polymeric triarylamines having conjugated moieties which are connected in a non-planar configuration, and copolymers of fluorene and triarylamines.

In some embodiments, the process further comprises forming an emissive layer by liquid deposition on the hole transport layer. In some embodiments, the emissive layer comprises an electroluminescent dopant and one or more host materials. In some embodiments, the emissive layer is formed by a liquid deposition technique selected from the group consisting of ink jet printing and continuous nozzle printing.

### EXAMPLES

The concepts described herein will be further described in the following examples, which do not limit the scope of the invention described in the claims.

### Example 1

This example illustrates the preparation of Compounds C and D.

The compounds were prepared according to the following scheme:

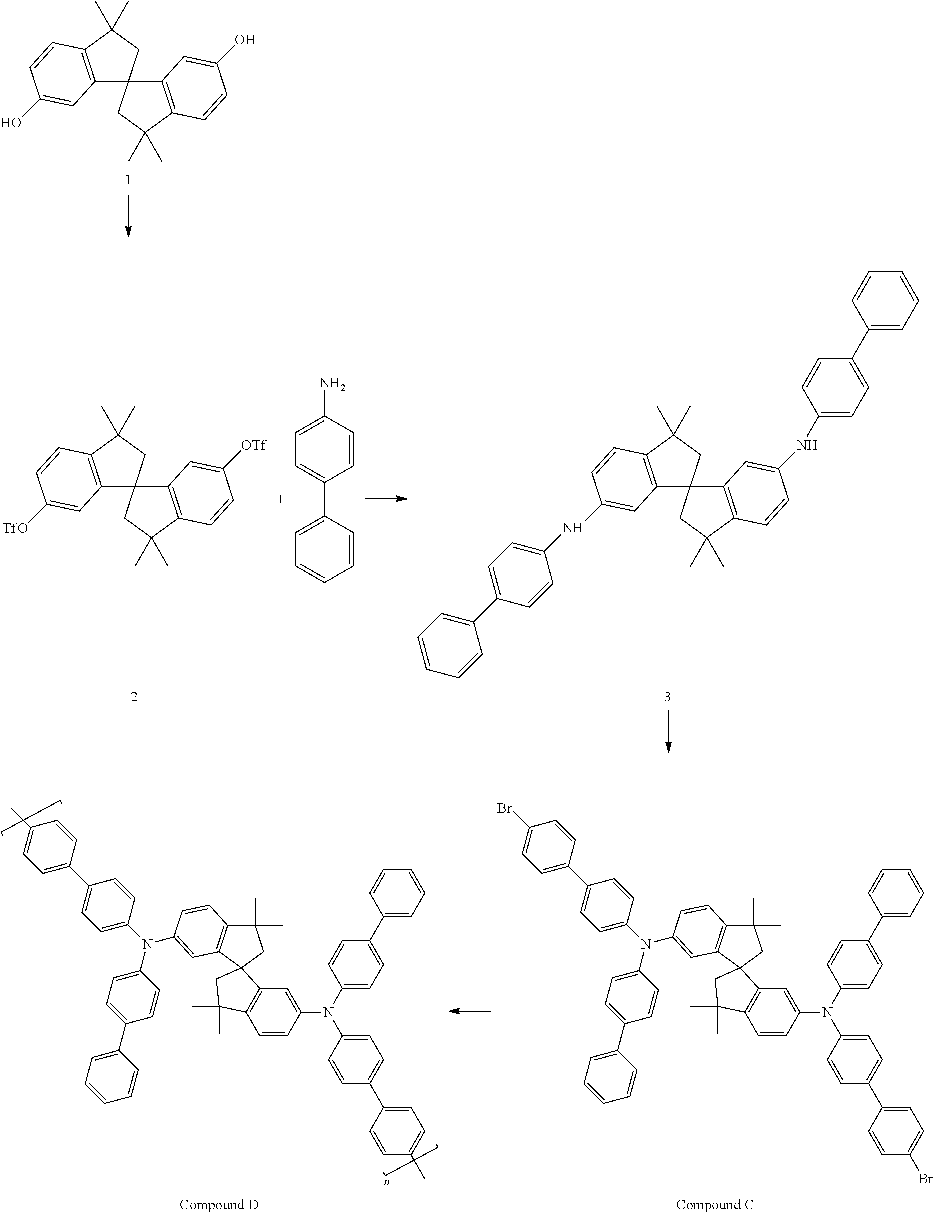

Spiro-bisphenol 1 was synthesized following the procedure reported by Chen, W.-F.; Lin, H.-Y.; Dai, S. A. Org. Letters 2004, 6, 2341.

Diol 1 (10.0 g, 32.4 mmol) was dissolved in 300 mL of dichloromethane and cooled to 0 C. Triflic anhydride (13.1 mL, 77.8 mmol) was slowly added and the reaction was allowed to slowly warm up to room temperature overnight. The resulting mixture was quenched with 0.5 M HCl. The layers were separated and the organic layer was washed with a sodium carbonate solution, water and then brine. Evaporation of the volatiles yielded a light pink solid in 81% yield (15 g).

Under an atmosphere of nitrogen a vial was charged with ditriflate 2 (3.07 g, 5.36 mmol), 4-aminobiphenyl (1.904 g, 11.3 mmol), Pd₂(dba)₃: (0.246 g, 0.268 mmol), 1,1′-bis(diphenylphosphino)ferrocene (0.297 g, 0.536 mmol) and toluene (40 mL). The resulting solution was stirred for 10 minutes followed by addition of NaO^{t}Bu (1.248 g, 13.4 mmol). The reaction was stirred at room temperature overnight followed by heating to 85° C. for 18 hrs. After cooling to room temperature, the resulting thick solution was diluted with toluene (˜100 mL) and filtered through a silica pad. Evaporation of the volatiles and purification on silica using a mixture of dicholoromethane and hexane (0-40%) as the eluent yielded compound 3 in 22% yield (0.73 g).

Under an atmosphere of nitrogen a vial was charged with diamine 3 (0.73 g, 1.20 mmol), 4,4′-iodobromobiphenyl (0.902 g, 2.51 mmol), Pd₂ (dba)₃ (0.044 g, 0.048 mmol), 1,1′-bis(diphenylphosphino)ferrocene (0.053 g, 0.096 mmol) and toluene (40 mL). The resulting solution was stirred for 10 minutes followed by addition of NaO^{t}Bu (0.242 g, 2.51 mmol). The reaction was heated to 90° C. for 22 hrs. After cooling to room temperature, the resulting thick solution was diluted with toluene (˜100 mL) and filtered through a silica pad. Evaporation of the volatiles and purification on silica using a mixture of dicholoromethane and hexane (40%) as the eluent yielded Compound C in 37% yield (0.479 g, 99% pure).

Compound C was polymerized using Yamamoto conditions to yield Compound D (GPC: Mn=2781, Mw=23,325).

### Example 2

This example illustrates the preparation of Compound B.

The compound was made according to the following scheme.

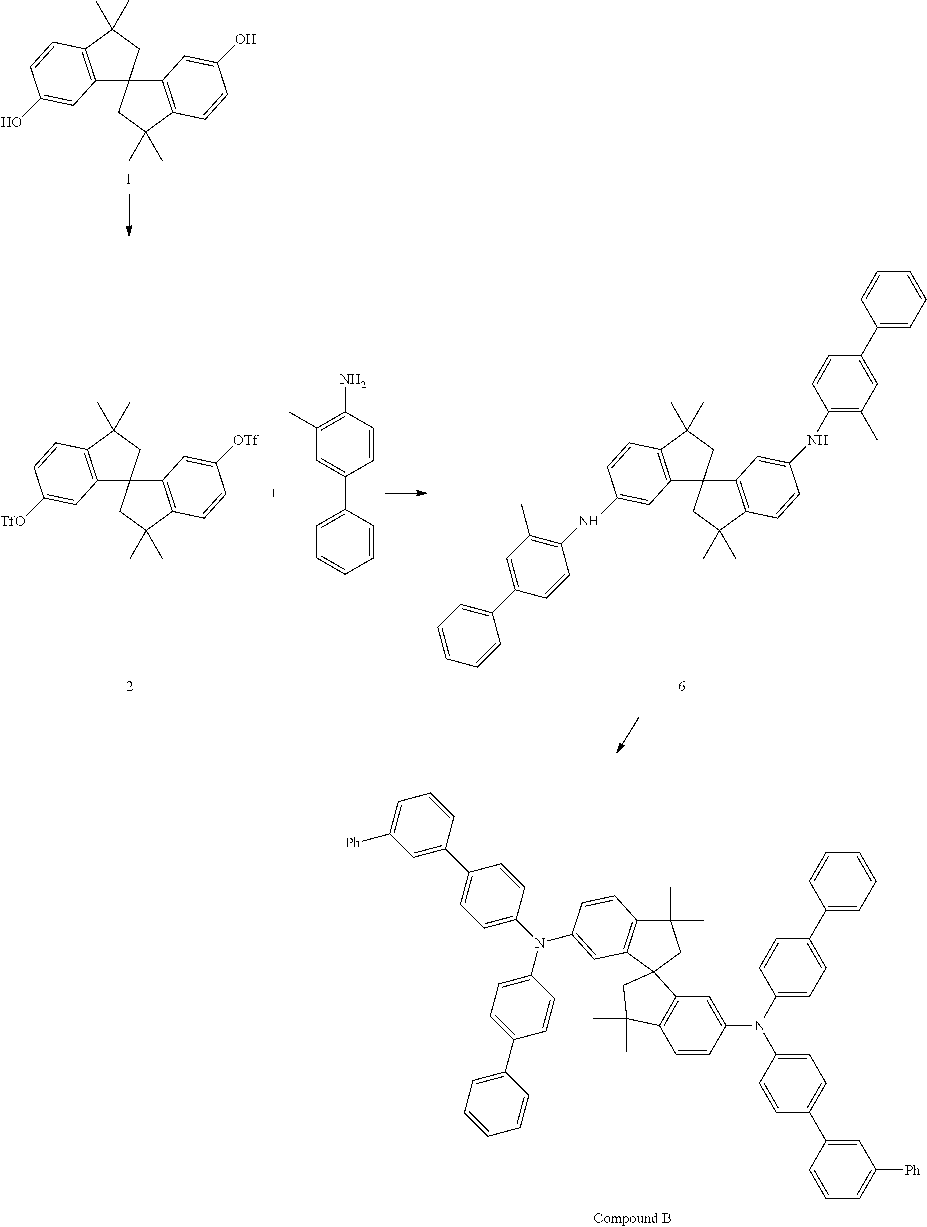 [SMILES: CC1(C)CC2(CC(C)(C)c3ccc(O)cc32)c2cc(O)ccc21 ; CC1(C)CC2(CC(C)(C)c3ccc(OS(=O)(=O)C(F)(F)F)cc32)c2cc(OS(=O)(=O)C(F)(F)F)ccc21 ; Cc1cc(-c2ccccc2)ccc1N ; Cc1cc(-c2ccccc2)ccc1Nc1ccc2c(c1)C1(CC2(C)C)CC(C)(C)c2ccc(Nc3ccc(-c4ccccc4)cc3C)cc21 ; CC1(C)CC2(CC(C)(C)c3ccc(N(c4ccc(-c5ccccc5)cc4)c4ccc(-c5cccc(-c6ccccc6)c5)cc4)cc32)c2cc(N(c3ccc(-c4ccccc4)cc3)c3ccc(-c4cccc(-c5ccccc5)c4)cc3)ccc21]

Under an atmosphere of nitrogen a vial was charged with ditriflate 2 (1.875 g, 3.27 mmol), 3-methylbiphenyl-4-amine (1.26 g, 6.88 mmol), Pd₂(dba)₃ (0.150 g, 0.164 mmol), 1,1′-bis(diphenylphosphino)ferrocene (0.182 g, 0.327 mmol) and toluene (30 mL). The resulting solution was stirred for 10 minutes followed by addition of NaO^{t}Bu (0.762 g, 8.19 mmol). The reaction was heated to 90° C. for 18 hrs. After cooling to room temperature, the resulting thick solution was diluted with toluene (˜100 mL) and filtered through a silica pad. Evaporation of the volatiles and purification on silica using a mixture of dicholoromethane and hexane (0-40%) as the eluent yielded compound 6 in 61% yield (1.28 g).

Under an atmosphere of nitrogen a vial was charged with diamine 6 (1.28 g, 2.00 mmol), 4-bromo-3-methyl-3′-phenyl-biphenyl (1.943 g, 6.00 mmol), Pd₂(dba)₃ (0.044 g, 0.048 mmol), 1,1′-bis(diphenylphosphino)ferrocene (0.019 g, 0.096 mmol) and toluene (30 mL). The resulting solution was stirred for 10 minutes followed by addition of NaO^{t}Bu (0.560 g, 6.0 mmol). The reaction was heated to 90° C. for 18 hrs. After cooling to room temperature, the resulting thick solution was diluted with toluene (˜100 mL) and filtered through a silica pad. Evaporation of the volatiles and purification on silica using a mixture of dicholoromethane and hexane (0-40%) as the eluent yielded Compound B in 44% yield (1.0 g).

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, references to values stated in ranges include each and every value within that range.

1. A process for forming a contained second layer over a first layer, said process comprising:
forming the first layer having a first surface energy;
treating the first layer with a priming material to form a priming layer;
exposing the priming layer patternwise with radiation resulting in exposed areas and unexposed areas;
developing the priming layer to effectively remove the priming layer from the unexposed areas resulting in a first layer having a pattern of priming layer, wherein the pattern of priming layer has a second surface energy that is higher than the first surface energy; and
forming the second layer by liquid deposition on the pattern of priming layer on the first layer;
wherein the priming material has Formula I 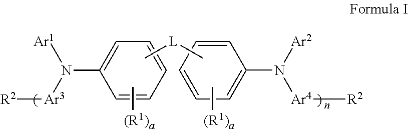
wherein:
Ar¹ through Ar⁴ are the same or different and are aryl groups;
L is selected from the group consisting of a spiro group, an adamantyl group, bicyclic cyclohexyl, deuterated analogs thereof, and substituted derivatives thereof;
R¹ is the same or different at each occurrence and is selected from the group consisting of D, F, alkyl, aryl, alkoxy, silyl, and a crosslinkable group, where adjacent R¹ groups can be joined together to form an aromatic ring;
R² is the same or different at each occurrence and is selected from the group consisting of H, D, and halogen;
a is the same or different at each occurrence and in an integer from 0-4; and
n is an integer greater than 0.

2. The process of claim 1, wherein the priming material has Formula II 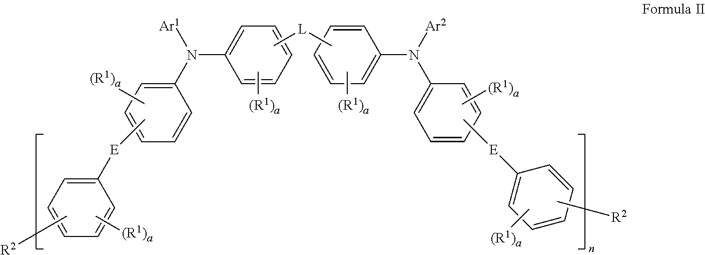
wherein:
Ar¹ and Ar² are the same or different and are aryl groups;
L is selected from the group consisting of a spiro group, an adamantyl group, bicyclic cyclohexyl, deuterated analogs thereof, and substituted derivatives thereof;
E is the same or different at each occurrence and is selected from the group consisting of a single bond, C(R³)₂, C(R⁴)₂C(R⁴)₂, O, Si(R³)₂, Ge(R³)₂;
R¹ is the same or different at each occurrence and is selected from the group consisting of D, F, alkyl, aryl, alkoxy, silyl, and a crosslinkable group, where adjacent R¹ groups can be joined together to form an aromatic ring;
R² is the same or different at each occurrence and is selected from the group consisting of H, D, and halogen;
R³ is the same or different at each occurrence and is selected from the group consisting of alkyl and aryl, where adjacent R³ groups can be joined together to form an aliphatic ring;
R⁴ is the same or different at each occurrence and is selected from the group consisting of H, D, and alkyl;
a is the same or different at each occurrence and in an integer from 0-4; and
n is an integer greater than 0.

3. The process of claim 1, wherein the priming material has Formula III 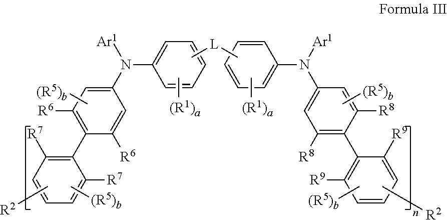
wherein:
Ar¹ and Ar² are the same or different and are aryl groups;
L is selected from the group consisting of a spiro group, an adamantyl group, bicyclic cyclohexyl, deuterated analogs thereof, and substituted derivatives thereof;
R¹ is the same or different at each occurrence and is selected from the group consisting of D, F, alkyl, aryl, alkoxy, silyl, and a crosslinkable group, where adjacent R¹ groups can be joined together to form an aromatic ring;
R² is the same or different at each occurrence and is selected from the group consisting of H, D, and halogen;
R⁵ is the same or different at each occurrence and is selected from the group consisting of D, F, alkyl, aryl, alkoxy, silyl, and a crosslinkable group;
R⁶ through R⁹ are the same or different at each occurrence and are selected from the group consisting of H, D, F, alkyl, aryl, alkoxy, silyl, and a crosslinkable group, with the proviso that at least one of R⁶ and R⁷ is alkyl or silyl, and at least one of R⁸ and R⁹ is alkyl or silyl;
a is the same or different at each occurrence and is an integer from 0-4;
b is the same or different at each occurrence and is an integer from 0-2; and
n is an integer greater than 0.

4. The process of claim 1, wherein Ar¹ and Ar² have Formula a 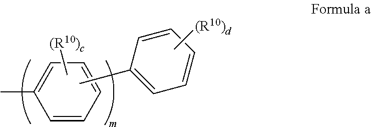
where:
R¹⁰ is the same or different at each occurrence and is selected from the group consisting of D, alkyl, alkoxy, siloxane and silyl;
c is the same or different at each occurrence and is an integer from 0-4;
d is an integer from 0-5; and
m is an integer from 1 to 5.

5. The process of claim 1, wherein Ar¹ and Ar² are selected from the group consisting of phenyl, biphenyl, terphenyl, deuterated derivatives thereof, and derivatives thereof having one or more substituents selected from the group consisting of alkyl, alkoxy, silyl, and a substituent with a crosslinking group.

6. The process of claim 1, wherein a=0.

7. The process of claim 2, wherein E is selected from the group consisting of C(R³)₂ and C(R⁴)₂C(R⁴)₂.

8. The process of claim 2, wherein R³ is selected from the group consisting of phenyl, biphenyl, and fluoroalkyl.

9. The process of claim 2, wherein R⁴ is selected from the group consisting of H and D.

10. The process of claim 3, wherein R⁶═R⁸=alkyl.

11. The process of claim 3, wherein R⁷═R⁹=alkyl.

12. A process for making an organic electronic device comprising an electrode having positioned thereover a first organic active layer and a second organic active layer, said process comprising
forming the first organic active layer having a first surface energy over the electrode;
treating the first organic active layer with a priming material to form a priming layer;
exposing the priming layer patternwise with radiation resulting in exposed areas and unexposed areas;
developing the priming layer to effectively remove the priming layer from the unexposed areas resulting in a first active organic layer having a pattern of priming layer, wherein the pattern of priming layer has a second surface energy that is higher than the first surface energy; and
forming the second organic active layer by liquid deposition on the pattern of priming layer on the first organic active layer;
wherein the priming material has Formula I 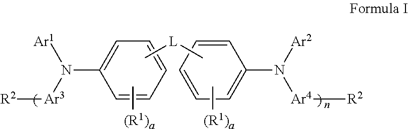
wherein:
Ar¹ through Ar⁴ are the same or different and are aryl groups;
L is selected from the group consisting of a spiro group, an adamantyl group, bicyclic cyclohexyl, deuterated analogs thereof, and substituted derivatives thereof;
R¹ is the same or different at each occurrence and is selected from the group consisting of D, F, alkyl, aryl, alkoxy, silyl, and a crosslinkable group, where adjacent R¹ groups can be joined together to form an aromatic ring;
R² is the same or different at each occurrence and is selected from the group consisting of H, D, and halogen;
a is the same or different at each occurrence and in an integer from 0-4; and
n is an integer greater than 0.

13. The process of claim 12, wherein the first active layer is a hole transport layer and the second active layer is an emissive layer.

14. The process of claim 12, wherein the first active layer is a hole injection layer and the second active layer is a hole transport layer.

15. The process of claim 14, wherein the hole injection layer comprises a conductive polymer and a fluorinated acid polymer.

16. The process of claim 14, wherein the hole injection layer consists essentially of a conductive polymer doped with a fluorinated acid polymer and inorganic nanoparticles.

17. The process of claim 14, further comprising forming an emissive layer by liquid deposition on the hole transport layer.

18. An organic electronic device comprising a first organic active layer and a second organic active layer positioned over an electrode, and further comprising a patterned priming layer between the first and second organic active layers, wherein said second organic active layer is present only in areas where the priming layer is present, and wherein the priming layer comprises a material having Formula I 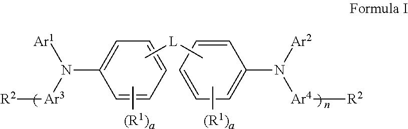
wherein:
Ar¹ through Ar⁴ are the same or different and are aryl groups;
L is selected from the group consisting of a spiro group, an adamantyl group, bicyclic cyclohexyl, deuterated analogs thereof, and substituted derivatives thereof;
R¹ is the same or different at each occurrence and is selected from the group consisting of D, F, alkyl, aryl, alkoxy, silyl, and a crosslinkable group, where adjacent R¹ groups can be joined together to form an aromatic ring;
R² is the same or different at each occurrence and is selected from the group consisting of H, D, and halogen;
a is the same or different at each occurrence and in an integer from 0-4; and
n is an integer greater than 0.
